(19) United States
(12) Patent Application Publication
(10) Pub. No.: US 2002/0167062 A1
(43) Pub. Date: Nov. 14, 2002

(54) Semiconductor device having a support structure

(75) Inventor: Hirochika Narita, Tokyo (JP)

Correspondence Address: Patent Group, Hutchins, Wheeler, Dittmar, 101 Federal Street, Boston, MA, 02110, US

(73) Assignee: NEC Corporation

(21) Appl. No.: 10/136,155

(22) Filed: May 1, 2002

(30) Foreign Application Priority Data
May 8, 2001 (JP) 2001-137211

(51) Int. Cl. H01L 31/0203

(52) U.S. Cl. 257/433

(57) ABSTRACT

A one-dimensional CCD sensor has a support structure including an elongate metallic base plate for mounting thereon a CCD chip and a resin housing encircling the metallic base plate at the periphery thereof. A pair of lead frames are electrically connected to the CCD chip and fixed onto the metallic base plate in the vicinities of both the ends of the metallic base plate. The CCD sensor is free from the thermal stress caused by the difference in the coefficient of thermal expansion between the metallic base plate and the lead frames.

### BACKGROUND OF THE INVENTION

(a) Field of the Invention

The present invention relates to a semiconductor device having a support structure and, more particularly, to the improvement of the structure of a support member for a semiconductor device such as a CCD sensor.

(b) Description of the Related Art

A one-dimensional CCD sensor includes, for example, 5000 to 10000 phototransistors arranged along a straight line to form a CCD semiconductor chip. This type of the CCD sensor is generally used as an image sensor in a copy machine, facsimile etc. The one-dimensional CCD sensor scans a paper in the direction normal to the direction of the arrangement of the phototransistors by moving the paper or the CCD sensor itself, to obtain the whole image of the paper.

Referring to FIGS. 1 and 2 showing a top plan view and a sectional view, respectively, of a support structure of a conventional one-dimensional CCD sensor, the support structure includes a ceramic base 31, a ceramic wall 35 and a lead frame 39 sandwiched therebetween. The lead frame 39 is bonded onto the ceramic base 31 and the ceramic wall 35 by using low-melting-point glass layer 36 to form a unitary body of the support structure. The support structure is capped with a cap member (not shown) at the top opening thereof after connecting together a CCD chip received in the support structure and the lead frame 39 by using bonding wires.

In the support structure shown in FIGS. 1 and 2, a thermal stress is generated between the lead frame 39 and the ceramic material due to the difference in the coefficient of thermal expansion therebetween. The thermal stress does not generally cause a deformation such as a warp in the ceramic base 31 because the ceramic material has an extremely high rigidity, whereas the thermal stress causes a deformation in the lead frame 39 having a higher coefficient of thermal expansion and a lower rigidity to distribute the stress distortion in the lead frame 39.

FIGS. 3 and 4 show a sectional view and a side view, respectively, of a conventional one-dimensional CCD sensor having the support structure shown in FIGS. 1 and 2. The CCD sensor 30 shown in the figures is fabricated by bonding a CCD chip 32 onto the ceramic base 31, connecting together the CCD chip 32 and the lead frame 39 by using bonding wires 38, encapsulating the CCD chip 32 by a glass cap 37, separating the lead frame 39 into a plurality of leads 39 by cutting-off the outer frame member of the lead frame 39, and bending the leads 39 in the vicinity of the periphery of the ceramic base 31.

In the CCD sensor 30 shown in FIGS. 3 and 4, the ceramic base 31 mounting thereon the CCD chip 32 has a function as a heat sink. The ceramic base 31, the ceramic wall 35 and the low-melting-point glass layer 36 bonding together the ceramic base 31 and the ceramic wall 35 define a hollow package 33 for receiving therein the CCD sensor 32. The glass cap 34 is fixed onto the ceramic wall 35 by using a resin layer 37 for encapsulating CCD sensor 32 within the hollow package 33. The leads 39 are electrically connected to the bonding pads of the CCD chip 32 by using the bonding wires 38 and extend through the glass layer 36 of the hollow package 33. The external bottom ends of the leads 39 are bonded onto terminals (not shown) of a printed circuit board and constitutes a part of the support structure of the CCD sensor 30. The CCD sensor 30 is about 500 mm long and about 15 mm wide, for example, in the external dimensions.

The conventional one-dimensional CCD sensor receives the image of a paper through a lens. If the CCD sensor has therein a deformation such as a curvature or warp, the focal point of the image of the paper deviates from the light-receiving surface of the CCD sensor, thereby degrading the image quality of the paper by the CCD sensor. Thus, it is important that the CCD sensor be free from such a deformation to obtain an excellent image quality. In the conventional CCD sensor having a length of 50 mm, for example, the metallic base generally involves a warp of about 100 micrometers, which limits the improvement of the image quality obtained by the CCD sensor.

### SUMMARY OF THE INVENTION

In view of the above, it is an object of the present invention to provide a semiconductor device, such as CCD sensor, having an improved support structure which reduces the deformation such as warp or curvature.

It is another object of the present invention to provide a hollow package for receiving therein a semiconductor chip for fabricating such a semiconductor device.

The present invention provides a semiconductor device including a semiconductor chip, a metallic base having a mounting surface for mounting thereon the semiconductor chip, a pair of lead frames fixed onto the metallic base for opposing each other and electrically connected to the semiconductor chip.

The present invention also provides a package for receiving therein a semiconductor chip, the package including a metallic base plate, a pair of lead frames each fixed onto the metallic base plate and having a plurality of leads, and a resin housing having a wall extending along an outer periphery of the metallic base, the leads of the lead frames protruding from the wall of the resin housing.

In accordance with the semiconductor chip and the package of the present invention, the metallic base (plate) generally has an excellent thermal radiation property, the lead frames have a small thickness and suited for mass production of the semiconductor device, and separation of the lead frame into a pair of lead frames alleviates the stress applied to the metallic base after fixing of the lead frames onto the metallic base.

The above and other objects, features and advantages of the present invention will be more apparent from the following description, referring to the accompanying drawings.

### BRIEF DESCRIPTION OF THE DRAWINGS

FIG. 1 is a top plan view of a support structure of a conventional CCD sensor.

FIG. 2 is a sectional view of the support structure of FIG. 1.

FIG. 3 is a sectional view of a conventional CCD sensor having the support structure shown in FIGS. 1 and 2.

FIG. 4 is a side view of the conventional CCD sensor of FIG. 3.

FIG. 5 is a cross-sectional view of a CCD sensor according to a first embodiment of the present invention.

FIG. 6 is a longitudinal side view, partly in section, of the CCD sensor of FIG. 5.

FIG. 7 is a top plan view of the support structure shown in FIGS. 5 and 6.

FIGS. 8A to 8G are top plan views of the CCD sensor of FIGS. 5 and 6, consecutively showing steps of fabrication process thereof.

FIG. 9 is a top plan view of a support structure of a CCD sensor according to a second embodiment of the present invention.

FIG. 10 is a top plan view of a support structure of a CCD sensor according to a third embodiment of the present invention.

FIG. 11 is a longitudinal-sectional view of a support structure of a CCD sensor according to a fourth embodiment of the present invention.

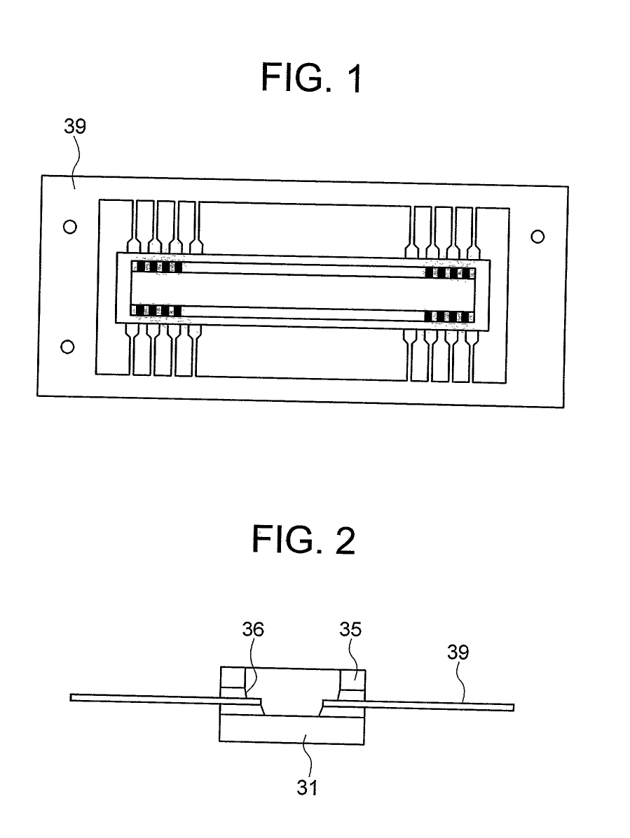

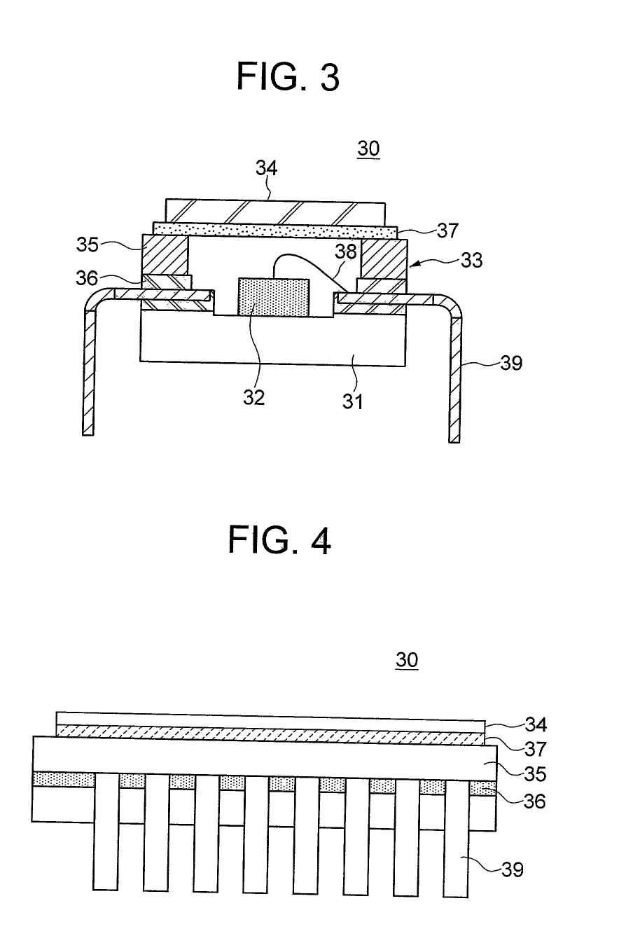

### PREFERRED EMBODIMENTS OF THE INVENTION

In a preferred embodiment of the present invention, the lead frames are insulated from the metallic base by an adhesive layer fixing the lead frames onto the metallic base. In an alternative, the lead frames may be fixed onto the metallic base by a rivet or spot welding. The metallic base may be coated with an insulator film at the boundary between the metallic base and each of the lead frames. The metallic base is preferably made of aluminum and in this case, the insulator film may be provided by an anodized aluminum.

The metallic base may be formed as an elongate metallic plate. The elongate metallic base plate may have a small-width portion in the vicinity of each of the lead frames. The metallic base may have an opening adjacent to a portion of each of the lead frames at which the each of the lead frames is connected to bonding wires. A single opening may extend between vicinities of the pair of lead frames instead of providing a pair of openings.

The present invention is preferably directed to a one-dimensional CCD sensor. In this case, a housing including a resin wall may be provided for receiving therein a CCD semiconductor chip mounted on the base plate. The resin wall of the housing may have a first portion above the mounting surface of the metallic base and a second portion below the mounting surface, wherein a ratio of a volume of the first portion to a volume of the second portion plus a volume of the metallic base preferably resides between 1:1 and 1:0.95. If the lead frames are fixed onto the metallic base by a rivet or spot welding, it is preferable that the lead frames be cut during the rivet or spot welding operation itself.

Now, the present invention is more specifically described with reference to accompanying drawings, wherein similar constituent elements are designated by similar reference numerals.

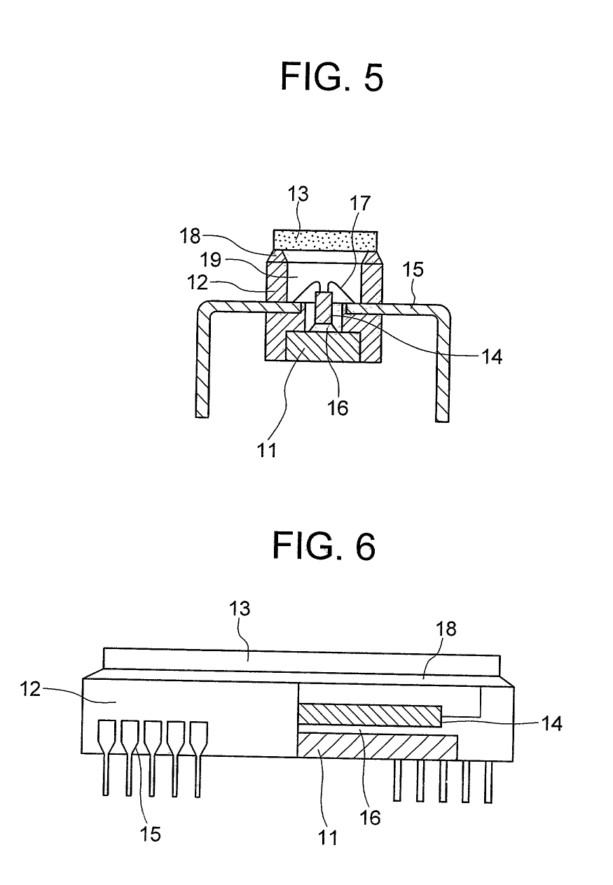

Referring to FIG. 5, a semiconductor device according to a first embodiment of the present invention is implemented as a CCD sensor. The CCD sensor generally designated by numeral 10 includes an elongate metallic base 11 made of an aluminum plate, a resin wall 12 fixed onto the outer periphery of the metallic base 11 for defining a cavity 19 of a housing, a glass cap 13 for capping the top opening of the housing, a CCD chip 14 fixed onto the elongate metallic base 11 and received in the cavity 19 of the resin wall 12, and a pair of lead frames separated into a plurality of copper leads 15 penetrating the resin wall 12 in the vicinities of both the ends of the elongate metallic plate 11.

The CCD chip 14 is fixed onto the mounting surface of the metallic base 11 by means of a mounting member 16, and thus received in the cavity 19 of the resin wall 12, with the center of the CCD chip 14 being aligned with the center of the resin wall 12 as viewed in the direction normal to the arrangement of the phototransistors. The resin wall 12 is made of plastic mold resin and forms the housing in association with the metallic base 11 and the glass cap 13, the housing receiving therein the CCD chip 14. The copper leads 15 are separated into two groups each disposed in the vicinity of one of the ends of the elongate metallic base 11, as shown in FIG. 6. Each copper lead 15 is bent in the vicinity of a portion thereof passing through the resin wall 12 of the housing, and constitutes the external terminals as well as the support of the CCD sensor 10 after being bonded onto a pad of a printed circuit board at the bottom of the each copper lead 15.

The resin wall 12 has a small width bottom portion in the vicinity of the CCD chip 14, and a large width top portion within which the bonding wires 17 connect bonding pads of the CCD chip 14 and the inner leads of the copper leads 15.

The CCD sensor 10 of the present embodiment has an excellent thermal radiation property due to the material of the metallic base 11 made of aluminum as well as the exposed bottom surface thereof. This allows a high-speed operation of the CCD sensor. The separation of the lead frame into a pair of lead frames, which are fixed onto the vicinities of both the ends of the elongate metallic base, allows excellent planarity of the mounting surface of the metallic base 11 due to alleviation of deformation thereof such as warp or curvature. Thus, the CCD sensor 10 of the present embodiment allows excellent focusing capability and thus improves the image quality by the CCD sensor 10. In addition, the simple structure lowers the cost for the CCD sensor.

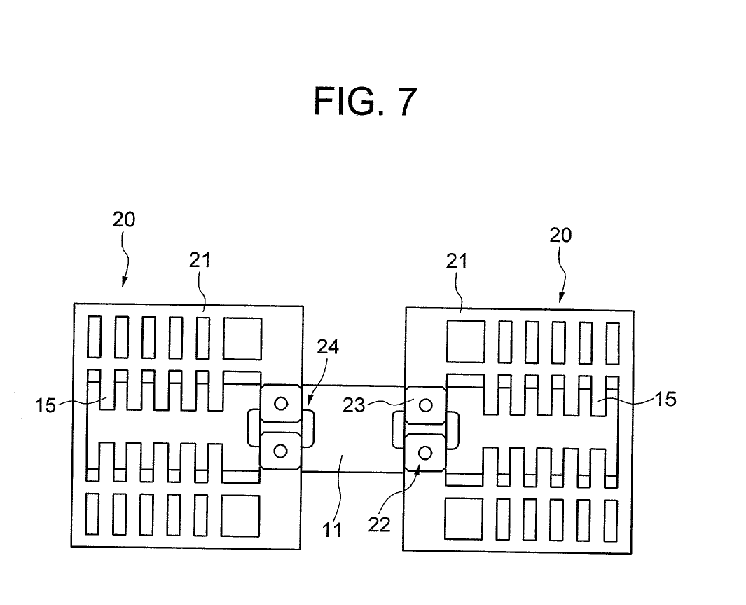

Referring to FIG. 7, the support structure of the CCD sensor 10 of the present embodiment is shown at a fabrication step just after the pair of lead frames 20 are fixed onto the metallic base 11. The pair of lead frames 20 are fixed onto the elongate metallic base 11 in the vicinities of the respective ends of the elongate metallic base 11, with a gap between the lead frames 20 being at the central portion of the metallic base 11. Each lead frame 20 includes a plurality of leads 15 each having an inner lead and an outer lead, and an outer frame member 21 mechanically coupling the leads 15 together. The metallic base 11 and each lead frame 20 are bonded together by rivets 22 at the outer frame member 21 of the each lead frame 20. The outer frame member 21 has a pair of large-thickness portions 23 for this purpose. The metallic base 11 has an opening 24 in the vicinity of the rivets 22 for alleviating the stress generated by the rivets 22.

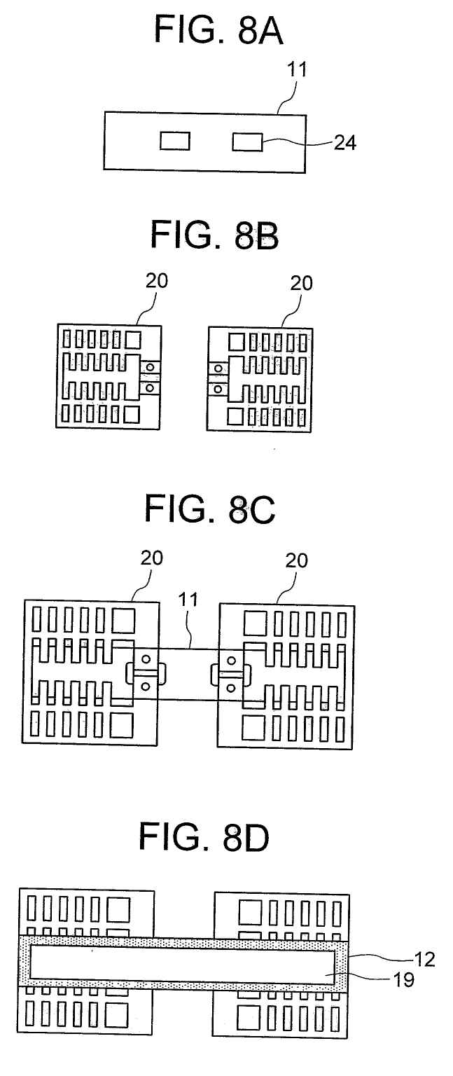

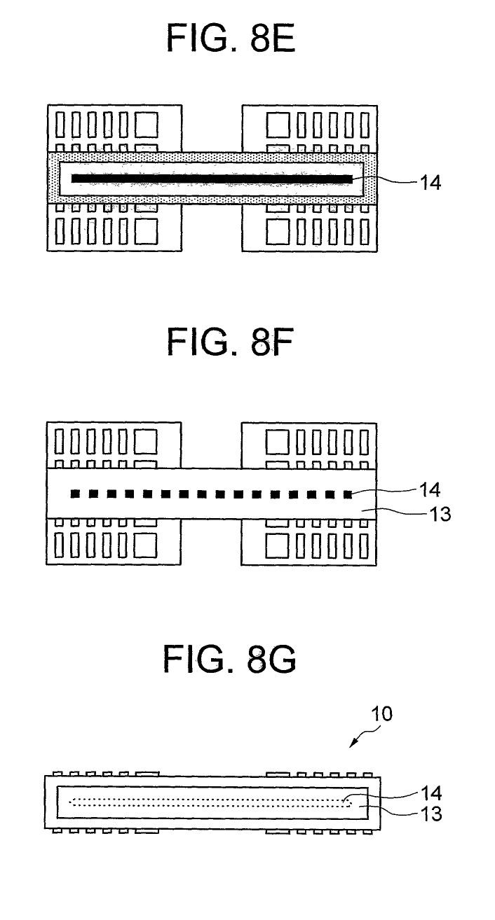

Referring to FIGS. 8A to 8G, there are shown consecutive steps of fabrication process of the CCD sensor of FIGS. 5 and 6. As shown in FIG. 8A, a metallic base plate 11 formed by pressing aluminum is subjected to machining to form a pair of openings 24 therein. A pair of lead frames 20 shown in FIG. 8B are separately provided, and fixed onto the metallic base 11 by using rivets, whereby a composite member of the lead frames 20 and the metallic base 11 is provided, as shown in FIG. 8C.

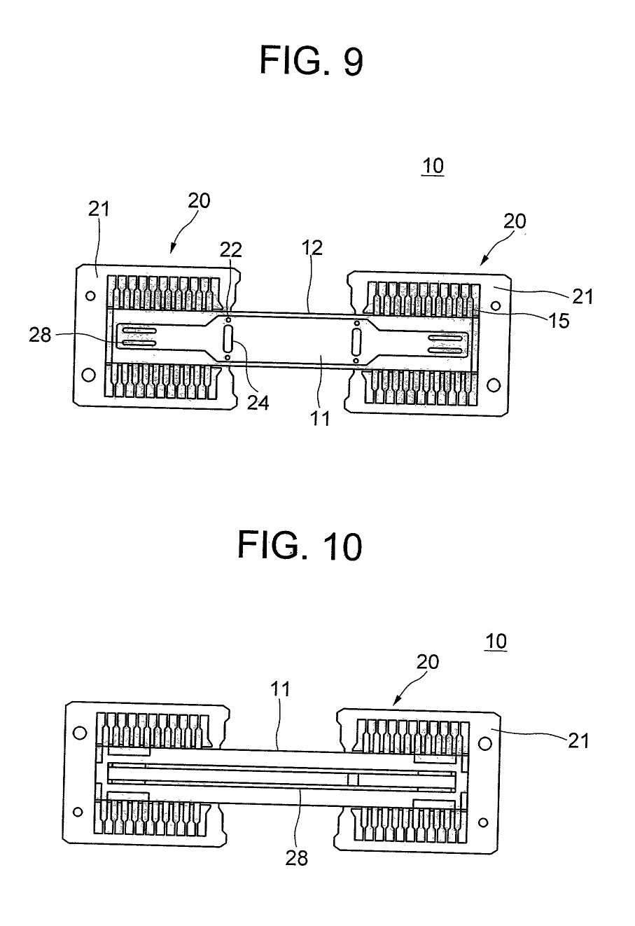

Subsequently, a resin wall 12 is formed on the outer periphery of the metallic base 11. More specifically, while inserting thrust pins formed within a mold die (not shown) into openings of the metallic base 11, such as 28 shown in FIGS. 9 and 10, to push the lead frames 20 upward, resin is injected into the mold die for molding the metallic base 11 and the lead frames 20, with the metallic base 11 being apart from the inner leads of the lead frames 20. The resin injected into the space between the metallic base 11 and the lead frames 20 adheres the metallic base 11 and the lead frames 20 together and insulate the metallic base 11 from the lead frames 20. The resin within the mold die defines the resin wall 12 having a cavity 19 therein, thereby forming a hollow package shown in FIG. 8D.

Thereafter, a CCD chip 14 is fixed onto the mounting surface of the metallic base 11, as shown in FIG. 8E, followed by electrically connecting the CCD chip 14 and the lead frames 20 together by using bonding wires. A glass cap 13 is then attached onto the top opening of the resin wall 12 for encapsulation of the CCD chip 14 by using ultra-violet-ray cured resin, as shown in FIG. 8F, followed by separating the leads 15 while cutting the outer frame member of the lead frame 20 from the leads 15 and bending the leads 15 to obtain the CCD sensor 10 shown in FIG. 8G.

A sample of the CCD sensor 10 described above was fabricated, which was 85 mm long in the external dimension. The sample had a warp as low as below 20 micrometers on the light receiving surface of the metallic base 11 for the CCD chip 14.

Referring to FIG. 9 as mentioned before, a CCD sensor 10, or a semiconductor device according to a second embodiment of the present invention, is shown at the stage just after the aluminum base 11 and a pair of lead frames 20 are molded together to form a package. The aluminum base 11 has a central large-width portion, and a pair of small-width portions at which the lead frames 20 are fixed onto the aluminum base 11 while insulated therefrom. The aluminum base 11 also has a pair of stress-alleviating openings 24 in the vicinities of the rivets 22 for alleviating the stress applied therefrom, and work openings 28 in the vicinities of the connections between the bonding wires and the leads 15 of the lead frames 20. The work openings 28 are used as the space for bonding the bonding wires and the leads 15. The whole surface of the aluminum base 11 is coated with an anodized aluminum formed by an almite process.

Referring to FIG. 10 mentioned before, a CCD sensor 10, or a semiconductor device according to a third embodiment of the present invention, differs from the CCD sensor of FIG. 9 in that the aluminum base 11 is formed roughly as a rectangular plate, and in that the aluminum base 11 has a single work opening 28 which extends between the vicinities of the pair of lead frames 20. In addition, in the CCD sensor 10 of the present embodiment, the lead frames 20 are fixed onto the aluminum base 11 by using an adhesive, which allows the stress-alleviating openings to be unnecessary.

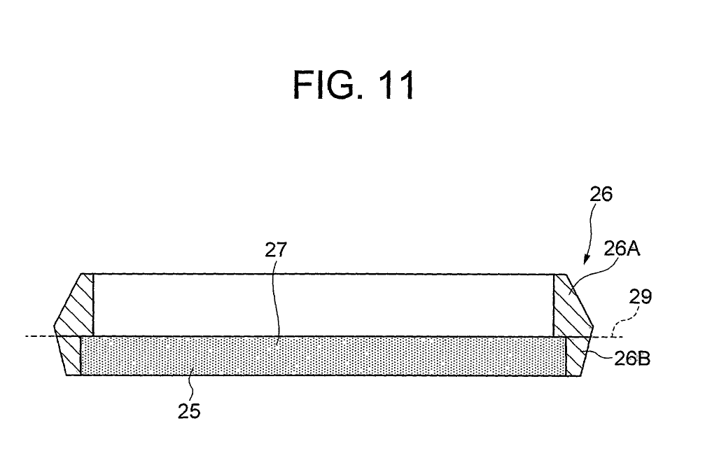

Referring to FIG. 11, a CCD sensor 10, or a semiconductor device according to a fourth embodiment of the present invention, includes a metallic base 25, a pair of lead frames (not shown), and a resin wall 26 made of silica-filled epoxy resin, for example. The silica-filled epoxy resin has an adjustable reduction factor between 0.3% and 0.5%, the reduction factor being measured under a specified condition wherein the material temperature falls from 175° C. to the room temperature after the molding operation.

An aluminum alloy is adopted as the material for the metal base 25. In the aluminum alloy having a thermal conductivity of 250 WmK, a coefficient of linear thermal expansion of 24 ppm for the aluminum alloy corresponds to a reduction factor of 0.35% under the specified condition as described above, whereas in the copper alloy having a thermal conductivity of 330 WmK, a coefficient of linear thermal expansion of 17 ppm for the copper alloy corresponds to a reduction factor of 0.25% under the specified condition. The aluminum alloy is selected here because the reduction factor, 0.35%, of the aluminum alloy better matches with the reduction factor, 0.3 to 0.5%, of the silica-filled epoxy resin. Since the lead frame itself does not significantly affect the volume reduction, a copper alloy is selected for the material for the lead frame in view of the excellent electric conductivity thereof.

The support structure shown in FIG. 11 assumes a configuration wherein the ratio of the volume of the top portion of the support structure above the mounting surface 29 for the CCD chip 14 to the volume of the bottom portion of the support structure below the mounting surface 29 resides between 1:1 and 1:0.95. The top portion of the support structure includes the top wall portion 26A of the resin wall 26, whereas the bottom portion of the support structure includes the metallic base 25 and the bottom wall portion 26B of the resin wall 26. It was confirmed by experiments that this specific ratio minimized the warp of the metallic base 25 after the package material was cooled to the room temperature.

Since the above embodiments are described only for examples, the present invention is not limited to the above embodiments and various modifications or alterations can be easily made therefrom by those skilled in the art without departing from the scope of the present invention.

For example, although the support structure of the semiconductor device according to the present invention is exemplified by the support structure of the CCD sensor in the above preferred embodiments, the support structure of the present invention can be applied to other general semiconductor devices so long as a smaller warp or curvature is desired therein.

What is claimed is:

1. A semiconductor device comprising a semiconductor chip, a metallic base having a mounting surface for mounting thereon said semiconductor chip, a pair of lead frames fixed onto said metallic base and electrically connected to said semiconductor chip.

2. The semiconductor device as defined in claim 1, wherein said lead frames are insulated from said metallic base by an adhesive layer fixing said lead frames to said metallic base.

3. The semiconductor device as defined in claim 1, wherein said lead frames are fixed onto said metallic base by rivet or spot welding, and wherein said metallic base has an opening adjacent to said rivet or spot welding.

4. The semiconductor device as defined in claim 1, wherein said metallic base is coated with an insulator film at least on an portion thereof adjacent to each of said lead frames.

5. The semiconductor device as defined in claim 4, wherein said metallic base is made of aluminum and said insulator film is made of anodized aluminum.

6. The semiconductor device as defined in claim 1, wherein said metallic base is formed as an elongate plate.

7. The semiconductor device as defined in claim 6, wherein said metallic base has a small-width portion in a vicinity of each of said lead frames.

8. The semiconductor device as defined in claim 6, wherein said metallic base has an opening adjacent to a portion of each of said lead frames at which said each of said lead frames is connected to bonding wires.

9. The semiconductor device as defined in claim 8, wherein said opening extends between vicinities of said pair of lead frames.

10. The semiconductor device as defined in claim 6, wherein said semiconductor device is a one-dimensional CCD sensor.

11. The semiconductor device as defined in claim 10, further comprising a housing made of resin and receiving therein said semiconductor chip on said base plate.

12. The semiconductor device as defined in claim 11, wherein said housing has a first portion above said mounting surface and a second portion below said mounting surface, and wherein a ratio of a volume of said first portion to a volume of said second portion plus a volume of said metallic base resides between 1:1 and 1:0.95.

13. A package for receiving therein a semiconductor chip, said package comprising a metallic base plate, a pair of lead frames each fixed onto said metallic base plate and having a plurality of leads, and a resin housing having a wall extending along an outer periphery of said metallic base, said leads of said lead frames passing through said wall of said resin housing.

14. The package as defined in claim 13, wherein said metallic base plate is formed as an elongate plate.

15. The package as defined in claim 13, wherein each of said lead frames is fixed onto said metallic base plate at a location where said each of said lead frames is cut.
